(19) United States
(12) Patent Application Publication
(10) Pub. No.: US 2014/0264833 A1
(43) Pub. Date: Sep. 18, 2014

(54) SEMICONDUCTOR PACKAGE AND METHOD FOR FABRICATING THE SAME

(71) Applicant: SK HYNIX, INC., Gyeonggi-do (KR)

(72) Inventors: Ho-Young SON, Gyeonggi-do (KR); Byung-Wook BAE, Gyeonggi-do (KR); Jong-Hoon KIM, Gyeonggi-do (KR)

(73) Assignee: SK HYNIX INC., Gyeonggi-do (KR)

(21) Appl. No.: 13/830,361

(22) Filed: Mar. 14, 2013

(51) Int. Cl. H01L 23/28

(52) U.S. Cl. CPC H01L 23/28
USPC 257/737

(57) ABSTRACT

A semiconductor package includes through-chip vias each penetrating through a semiconductor substrate and having a protrusion that is protruded from the backside of the semiconductor substrate; and a passivation layer formed on the backside of the semiconductor substrate and planarized corresponding to the surface of the protrusions of the through-chip vias, wherein the passivation layer includes a first insulation layer formed on the side of the protrusions of the through-chip vias and the backside of the semiconductor substrate, and a second insulation layer formed over the first insulation layer.

### BACKGROUND

1. Field

Exemplary embodiments of the present invention relate to a method for fabricating a semiconductor device, and more particularly, to a semiconductor package including through-chip vias, and a method for fabricating the semiconductor package.

2. Description of the Related Art

As the demands for miniaturized high-performance electronic devices and mobile devices increase, semiconductor memory devices are required to be smaller and smaller with higher capacity. Among the methods for increasing the storage capacity of a semiconductor memory device is a method of mounting and assembling a plurality of semiconductor chips in the inside of one semiconductor package. According to the method, the storage capacity of a semiconductor device may be easily increased by changing the packaging method. The method also has many advantages in terms of money, effort and time for research and development. Therefore, semiconductor memory manufacturers are trying to increase the storage capacity of a semiconductor memory device through a multi-chip package where a plurality of semiconductor chips are mounted on one semiconductor package.

For the method of mounting a plurality of semiconductor chips on one semiconductor package, there is a method of horizontally mounting multiple semiconductor chips and a method of vertically mounting multiple semiconductor chips. Since electronic devices pursue miniaturization, most semiconductor memory manufacturers prefer a stack-type multi-chip package where semiconductor chips are stacked vertically and packaged. An example of the stack-type multi-chip package structure is a package structure using through-chip vias, e.g., through-silicon vias (TSVs). In a stack-type multi-chip package employing the through-chip vias, the through-chip vias are formed in the inside of each semiconductor chip in the stage of wafer, and the vertically stacked semiconductor chips are physically and electrically connected to each other.

### SUMMARY

An embodiment of the present invention is directed to a semiconductor package that may prevent electrical bridge between a substrate and the bumps on the backside of the substrate by protecting the backside of the substrate while a semiconductor including through-chip vias is packaged, and a method for fabricating the semiconductor package.

Another embodiment of the present invention is directed to a semiconductor package that may prevent the penetration of a contaminant that is diffused along the side of through-chip vias on the backside of a substrate while a semiconductor including the through-chip vias is packaged, and a method for fabricating the semiconductor package.

Another embodiment of the present invention is directed to a semiconductor package where each semiconductor chip has a backside structure for stable bonding with another chip, and a method for fabricating the semiconductor package.

In accordance with an embodiment of the present invention, a semiconductor package includes through-chip vias each penetrating through a semiconductor substrate and having a protrusion that is protruded from the backside of the semiconductor substrate, and a passivation layer formed on the backside of the semiconductor substrate and planarized corresponding to the surface of the protrusions of the through-chip vias, wherein the passivation layer includes a first insulation layer formed on the side of the protrusions of the through-chip vias and the backside of the semiconductor substrate, and a second insulation layer formed over the first insulation layer.

The first insulation layer may be an oxide layer, and the second insulation layer may be a nitride layer. The first insulation layer may be a nitride layer, and the second insulation layer may be an oxide layer.

In accordance with another embodiment of the present invention, a semiconductor package may include through-chip vias each penetrating through a semiconductor substrate and having a protrusion that is protruded from the backside of the semiconductor substrate, and a passivation layer formed on the backside of the semiconductor substrate and planarized corresponding to the surface of the protrusions of the through-chip vias, wherein the passivation layer includes a first insulation layer formed on the side of the protrusions of the through-chip vias and the backside of the semiconductor substrate, a second insulation layer formed over the to first insulation layer, and a third insulation layer formed over the second insulation layer.

The first insulation layer may be a nitride layer, and the second insulation layer may be an oxide layer, and the third insulation layer may be a nitride layer.

In accordance with another embodiment of the present invention, a semiconductor package may include through-chip vias each penetrating through a semiconductor substrate and having a protrusion that is protruded from the backside of the semiconductor substrate, and a passivation layer formed on the backside of the semiconductor substrate and planarized corresponding to the surface of the protrusions of the through-chip vias, wherein the passivation layer is a nitride layer or a polymer layer formed on the side of protrusions of the through-chip vias and the backside of the semiconductor substrate.

The semiconductor package may further include bumps formed contacting the surface of each protrusion of the through-chip vias. The bumps may be formed contacting the entire or part of the surface of each protrusion of the through-chip vias, and the bumps may be formed to be stretched to the upper portion of the passivation layer.

The semiconductor package may further include a liner layer interposed between the first insulation layer and the side of each protrusion of the through-chip vias. The semiconductor package may further include a barrier layer interposed between the liner layer and the side of each protrusion of the through-chip vias.

### BRIEF DESCRIPTION OF THE DRAWINGS

FIG. 1 is a cross-sectional view illustrating a semiconductor package in accordance with an embodiment of the present invention.

FIG. 2 is a cross-sectional view illustrating a semiconductor package in accordance with another embodiment of the present invention.

FIG. 3 is a cross sectional view illustrating a semiconductor package in accordance with yet another embodiment of the present invention.

FIGS. 4A to 4C are cross-sectional views illustrating bumps added to the backside of the improved semiconductor packages in accordance with the embodiments of the present invention.

FIGS. 5A to 5C are cross-sectional views illustrating bumps added to the backside structures of the improved semiconductor packages in accordance with the embodiments of the present invention.

FIGS. 6A to 6D are cross-sectional views illustrating a process of fabricating the improved semiconductor package of FIG. 4A.

FIGS. 7A to 7D are cross-sectional views illustrating a process of fabricating the improved semiconductor package of FIG. 4B.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

FIG. 1 is a cross-sectional view illustrating a semiconductor package in accordance with an embodiment of the present invention.

Referring to FIG. 1, the semiconductor package in accordance with the embodiment of the present invention includes a semiconductor substrate 100 having a front side A and a backside B. The semiconductor substrate 100 may be a silicon substrate. The semiconductor substrate 100 has through-vias 103 that penetrate the semiconductor substrate 100 from the front side A to the backside B. Although not illustrated in the drawing, the through-vias may be blind vias. A via forming process is generally divided into a via first step, a via middle step, and a via last step. In the improved semiconductor package, vias may be formed in a certain step.

A through-silicon via (TSV) 102 is formed in the inside of each through-via 103. The through-silicon via 102 has a protrusion 102A that penetrates through the semiconductor substrate 100 and is protruded from the backside B of the semiconductor substrate 100. The through-silicon via 102 may be formed of a conductor such as polysilicon, metal, or a combination thereof. The metal may be copper (Cu) or tungsten (W).

A liner layer 101A may be formed between the through-silicon vias 102 and the semiconductor substrate 100. The liner layer 101A may be formed of an insulation material, such as an oxide, e.g., SiOₓ, a nitride, e.g. SiN_{X}, or a polymer. The liner layer 101A may be conformally formed along the internal wall of the through-vias 103. When the through-silicon vias 102 are formed of copper (Cu), a barrier layer 101B for preventing the diffusion of copper (Cu) may be formed. For example, when the liner layer 101A is formed of a nitride, e.g., SiN and Si₃N₄, the liner layer 101A may serve as a barrier against copper (Cu). Therefore, it does not have to form the barrier layer 101B in this case. The barrier layer 101B may be formed of a conductive metal oxide or a conductive metal nitride.

The liner layer 101A and the barrier layer 101B may be conformally formed on the side of the through-silicon vias 102, and they may be formed even on the side of the protrusions 102A of the through-silicon vias 102. The surface S of the protrusions 102A of the through-silicon vias 102 are not covered with the liner layer 101A and the barrier layer 101B.

A passivation layer 106 is formed on the backside B of the semiconductor substrate 100. The passivation layer 106 may be formed to have a height from the backside B of the semiconductor substrate 100 to the surface S of the protrusions 102A of the through-silicon vias 102 and then planarized. The passivation layer 106 may include a first insulation layer 104A and a second insulation layer 105A. The first insulation layer 104A may be formed adjacent to the upper portion of the backside B of the semiconductor substrate 100 and the side of the protrusions 102A of the through-silicon vias 102. According to one embodiment of the present invention, the first insulation layer 104A may be an oxide layer, and the second insulation layer 105A may be a nitride layer. According to another embodiment of the present invention, the first insulation layer 104A may be a nitride layer, and the second insulation layer 105A may be an oxide layer.

FIG. 2 is a cross-sectional view illustrating a semiconductor package in accordance with another embodiment of the present invention.

Referring to FIG. 2, the improved semiconductor package includes a semiconductor substrate 100, through-silicon vias 102 each having a protrusion 102A, a liner layer 101A, and a barrier layer 1018. The improved semiconductor package further includes a first nitride layer 210A, an oxide layer 220A, and a second nitride layer 230A as a passivation layer on the backside B of the semiconductor substrate 100.

Since the semiconductor substrate 100, the through-silicon vias 102 each having the protrusion 102A, the liner layer 101A, and the barrier layer 101B are described in the above-described embodiment of the present invention, description on them are omitted herein. The barrier layer 101B may be omitted.

As described above, the semiconductor package in accordance with this embodiment of the present invention includes a nitride-oxide-nitride (NON) structure as a passivation layer on the backside B of the semiconductor substrate 100. Since the other structures are described in the aforementioned embodiment of the present invention, description on them is omitted.

The semiconductor package in accordance with this embodiment of the present invention is advantageous in that the second nitride layer 230A minimizes the diffusion of a contaminant into the semiconductor substrate 100 through the side of the protrusions 102A of the through-silicon vias 102.

FIG. 3 is a cross-sectional view illustrating a semiconductor to package in accordance with yet another embodiment of the present invention.

Referring to FIG. 3, the improved semiconductor package includes a semiconductor substrate 100, through-silicon vias 102 each having a protrusion 102A, a liner layer 101A, and a barrier layer 1018. The improved semiconductor package further includes a single layer of an insulation layer 310 as a passivation layer on the backside B of the semiconductor substrate 100. The insulation layer 310 may be a nitride layer or a polymer layer. In other words, the semiconductor package in accordance with the embodiment of the present invention may include a single layer of the insulation layer 310 that is formed of a nitride or a polymer as the passivation layer on the backside B of the semiconductor substrate 100.

Since the semiconductor substrate 100, the through-silicon vias 102 each having the protrusion 102A, the liner layer 101A, and the barrier layer 101B are described in the above-described embodiment of the present invention, description on them are omitted herein.

FIGS. 4A to 4C are cross-sectional views illustrating bumps added to the backside structures of the improved semiconductor packages in accordance with the embodiments of the present invention.

Referring to FIGS. 4A to 4C, the improved semiconductor packages include a semiconductor substrate 100, through-silicon vias 102 each having a protrusion 102A, a liner layer 101A, a barrier layer 101B, and a passivation layer 106, 200 and 310. The improved semiconductor package may further include bumps 410 formed on the surface S of each protrusion 102A of the through-silicon vias 102.

Since the semiconductor substrate 100, the through-silicon vias 102 each having the protrusion 102A, the liner layer 101A, the barrier layer 101B, and the passivation layer 106, 200 and 310 are described in the above-described embodiment of the present invention, description on them are omitted herein. The barrier layer 101B may be omitted.

The bumps 410 may be formed to directly contact the entire surface S of the protrusions 102A of the through-silicon vias 102. Also, the bumps 410 may be formed to be stretched to the upper portion of the passivation layer 106, 200 and 310 formed around the protrusions 102A of the through-silicon vias 102.

The bumps 410 may include a copper (Cu) layer 410A, a nickel (Ni) layer 410B, and a gold (Au) layer 410C that are sequentially stacked on the surface S of the protrusions 102A of the through-silicon vias 102.

FIGS. 5A to 5C are cross-sectional views illustrating bumps added to the backside structures of the improved semiconductor packages in accordance with the embodiments of the present invention.

Referring to FIGS. 5A to 5C, the improved semiconductor packages include a semiconductor substrate 100, through-silicon vias 102 each having a protrusion 102A, a liner layer 101A, a barrier layer 101B, and a passivation layer 106, 200 and 310. The improved semiconductor package may further include bumps 510 formed on the surface S of the protrusions 102A of the through-silicon vias 102.

Since the semiconductor substrate 100, the through-silicon vias 102 each having the protrusion 102A, the liner layer 101A the barrier layer 101B, and the passivation layer 106, 200 and 310 are described in the above-described embodiment of the present invention, description on them are omitted herein. The barrier layer 101B may be omitted.

The bumps 510 may be formed to contact part of the surface S of the protrusions 102A of the through-silicon vias 102. Also, the bumps 510 may be formed to be stretched to the upper portion of the passivation layer 106, 200 and 310. Herein, the part of the surface S of the protrusions 102A of the through-silicon vias 102 may not be covered with the bumps 510. The bumps 510 may include a copper (Cu) layer 510A, a nickel (Ni) layer 510B, and a gold (Au) layer 510C that are sequentially stacked on the surface S of the protrusions 102A of the through-silicon vias 102.

FIGS. 6A to 6D are cross-sectional views illustrating a process of fabricating the improved semiconductor package of FIG. 4A.

Referring to FIG. 6A, the through-silicon via 102 penetrating through the semiconductor substrate 100. Hereafter, a method for forming the through-silicon vias 102 is described. Through-vias 103 may be formed by etching the semiconductor substrate 100, or a wafer obtained after a predetermined process is performed, in a predetermined depth from the front side A. Subsequently, a liner layer 101A and a barrier layer 101B may be formed in the inside of each through-via 103. Subsequently, the through-vias 103 may be filled with a conductive layer by depositing the conductive layer or performing a Chemical Mechanical Polishing (CMP) process. Although not illustrated in the drawing, a circuit may be formed by additionally performing a process of forming metal lines over the front side A of the semiconductor substrate 100. Subsequently, the backside B of the semiconductor substrate 100 may be polished. The backside B physically polished first, and then a dry etch process or a CMP process may be performed. The physical polishing may be a back grinding process. As a result of the polishing process, the through-silicon vias 102 come to have protrusions 102A that are protruded from the backside B of the semiconductor substrate 100. Herein, the liner layer 101A and the barrier layer 101B may cover the surface S of the protrusions 102A of the through-silicon vias 102.

Referring to FIG. 6B, a first insulation layer 104 and a second insulation layer 105 may be stacked on the backside of a wafer. The first insulation layer 104 and the second insulation layer 105 function as diffusion barriers for preventing migration of copper (Cu) into the side of the through-silicon vias 102, function as stress buffers, and function as planarizers in the subsequent CMP process. In short, the first insulation layer 104 and the second insulation layer 105 function as typical passivation layers.

Referring to FIG. 6C, the first insulation layer 104 and the second insulation layer 105 are planarized. The planarization may be a CMP process or a mechanical polishing process. The planarization process may be performed until the surface S of the backside of the through-silicon vias 102 is exposed. As a result of the planarization process, the surface S of the backside of the through-silicon vias 102 is exposed.

The patterned first insulation layer 104A and the patterned second insulation layer 105A obtained as a result of the planarization process are referred to as a passivation layer 106 for the sake of convenience in description.

Referring to FIG. 6D, bumps 410 contacting the protrusions 102A of the through-silicon vias 102 may be formed. The bumps 410 are formed to contact the entire or part of the surface S of the protrusions 102A of the through-silicon vias 102, and the bumps 410 may be formed to be stretched to the upper portion of the passivation layer 106. The bumps 410 may include a copper (Cu) layer 410A, a nickel (Ni) layer 410B, and a gold (Au) layer 410C that are sequentially stacked on the surface S of the protrusions 102A of the through-silicon vias 102.

FIGS. 7A to 7D are cross-sectional views illustrating a process of fabricating the improved semiconductor package of FIG. 4B.

Referring to FIG. 7A, through-silicon vias 102 penetrating through a semiconductor substrate 100 and having protrusions 102A are formed. Since specific methods for forming the through-silicon vias 102, a liner layer 101A, and a barrier layer 101B have been described in the above-described embodiment of the present invention, description on them is omitted herein.

Referring to FIG. 7B, a first nitride layer 210, an oxide layer 220, and a second nitride layer 230 are sequentially stacked on the backside of a wafer. A sacrificial layer 240 for planarization may be formed over the second nitride layer 230. The sacrificial layer 240 may be an oxide layer.

Referring to FIG. 7C, the substrate structure is planarized until the surfaces of the protrusions 102A of the through-silicon vias 102 and the second nitride layer 230 are exposed. The planarization may be a CMP process.

Referring to FIG. 7D, bumps 410 contacting the protrusions 102A of the through-silicon vias 102 may be formed. The bumps 410 are formed to contact the entire or part of the surface S of the protrusions 102A of the through-silicon vias 102, and the bumps 410 may be formed to be stretched to the upper portion of a passivation layer 106. The bumps 410 may include a copper (Cu) layer 410A, a nickel (Ni) layer 410B, and a gold (Au) layer 410C that are sequentially stacked on the surface S of the protrusions 102A of the through-silicon vias 102.

The improved semiconductor package has a barrier function by forming an insulation layer on the backside of a semiconductor substrate, e.g., a silicon substrate, from which through-silicon vias (TSVs) are protruded. For this reason, even though the overlay margin between the through-silicon vias on the backside and bumps is short, electrical bridge between the semiconductor substrate and the bumps may be prevented from occurring. Also, the improved semiconductor package may prevent penetration of a contaminant that may be diffused along the side of the through-silicon vias on the backside of the semiconductor substrate.

Also, the improved semiconductor package provides a stable backside structure and has an improved bonding performance among semiconductor chips. For reference, the detailed description is described based on the specification of the Korean Patent Publication No. 2012-0120776, filed on Apr. 25, 2011, entitled “SEMICONDUCTOR PACKAGE AND METHOD FOR MANUFACTURING THE SAME”, which is incorporated herein by reference.

Therefore, in accordance with the embodiment of the present invention, defects that may occur in the course of a stack packaging process using through-silicon vias may be prevented, and thus throughput and cut down on production cost may be improved.

While the present invention has been described with respect to the specific embodiments, it will be apparent to those skilled in the art that various changes and modifications may be made without departing from the spirit and scope of the invention as defined in the following claims.

What is claimed is:

1. A semiconductor package, comprising:
through-chip vias each penetrating through a semiconductor substrate and having a protrusion that is protruded from a backside of the semiconductor substrate; and
a passivation layer formed on the backside of the semiconductor substrate and planarized corresponding to the surface of the protrusions of the through-chip vias,
wherein the passivation layer includes a first insulation layer formed on the side of the protrusions of the through-chip vias and the backside of the semiconductor substrate, and a second insulation layer formed over the first insulation layer.

2. The semiconductor package of claim 1, wherein the first insulation layer is an oxide layer, and the second insulation layer is a nitride layer.

3. The semiconductor package of claim 1, wherein the first insulation layer is a nitride layer, and the second insulation layer is an oxide layer.

4. The semiconductor package of claim 1, further comprising:
bumps formed contacting the surface of each protrusion of the through-chip vias.

5. The semiconductor package of claim 4, wherein the bumps are formed contacting the entire or part of the surface of each protrusion of the through-chip vias, and the bumps are formed to be stretched to the upper portion of the passivation layer.

6. The semiconductor package of claim further comprising:
a liner layer interposed between the first insulation layer and the side of each protrusion of the through-chip vias.

7. The semiconductor package of claim 6, further comprising:
a barrier layer interposed between the liner layer and the side of each protrusion of the through-chip vias.

8. A semiconductor package, comprising:
through-chip vias each penetrating through a semiconductor substrate and having a protrusion that is protruded from a backside of the semiconductor substrate; and
a passivation layer formed on the backside of the semiconductor substrate and planarized corresponding to the surface of the protrusions of the through-chip vias,
wherein the passivation layer includes a first insulation layer formed on the side of the protrusions of the through-chip vias and the backside of the semiconductor substrate, a second insulation layer formed over the first insulation layer, and a third insulation layer formed over the second insulation layer.

9. The semiconductor package of claim 8, wherein the first insulation layer is a nitride layer, and the second insulation layer is an oxide layer, and the third insulation layer is a nitride layer.

10. The semiconductor package of claim 8, further comprising:
bumps formed contacting the surface of each protrusion of the through-chip vias.

11. The semiconductor package of claim 10, wherein the bumps are formed contacting the entire or part of the surface of each protrusion of the through-chip vias, and the bumps are formed to be stretched to the upper portion of the passivation layer.

12. The semiconductor package of claim 8, further comprising:
a liner layer interposed between the first insulation layer and the side of each protrusion of the through-chip vias.

13. The semiconductor package of claim 12, further comprising:
a barrier layer interposed between the liner layer and the side of each protrusion of the through-chip vias.

14. A semiconductor package, comprising:
through-chip vias each penetrating through a semiconductor substrate and having a protrusion that is protruded from a backside of to the semiconductor substrate; and
a passivation layer formed on the backside of the semiconductor substrate and planarized corresponding to the surface of the protrusions of the through-chip vias,
wherein the passivation layer is a nitride layer or a polymer layer formed on the side of protrusions of the through-chip vias and the backside of the semiconductor substrate.

15. The semiconductor package of claim 14, further comprising:
bumps formed contacting the surface of each protrusion of the through-chip vias.

16. The semiconductor package of claim 15, wherein the bumps are formed contacting the entire or part of the surface of each protrusion of the through-chip vias, and the bumps are formed to be stretched to the upper portion of the passivation layer.

17. The semiconductor package of claim 14, further comprising:
a liner layer interposed between the first insulation layer and the side of each protrusion of the through-chip vias.

18. The semiconductor package of claim 17, further comprising:
a barrier layer interposed between the liner layer and the side of each protrusion of the through-chip vias.
